(19) United States
(12) Patent Application Publication
(10) Pub. No.: US 2026/0081472 A1
(43) Pub. Date: Mar. 19, 2026

(54) Method and Apparatus for Wireless Power Transfer with Resonant Capacitor Switching

(71) Applicant: NuVolta Technologies (Hefei) Co., Ltd., Hefei (CN)

(72) Inventors: Zhijun Luo, Shanghai (CN); Dongchao Li, Shanghai (CN); Hang Meng, Shanghai (CN)

(21) Appl. No.: 18/896,753

(22) Filed: Sep. 25, 2024

(30) Foreign Application Priority Data
Sep. 19, 2024 (CN) CN202411312570.4

(51) Int. Cl. H02J 50/12; H03K 17/0812; H03K 17/13

(52) U.S. Cl. CPC H02J 50/12; H03K 17/08122; H03K 17/133

(57) ABSTRACT

An apparatus for wireless power transfer includes a resonant circuit comprising: a transmitter coil; a first capacitor connected with the transmitter coil in series; and a second capacitor connected in series with a first switch. The second capacitor and the first switch are connected in parallel with the first capacitor. A control circuit is connected to the resonant circuit, and is configured to: detect whether an event of a voltage across the first capacitor or a current of the transmitter coil occurs; and when detecting that the event occurs, control to turn on the first switch in response to a signaling of turning on the first switch. A method for controlling switching-in of the second capacitor is also provided.

### CROSS-REFERENCE TO RELATED APPLICATIONS

This application claims priority to Chinese patent application No. 202411312570.4, filed on Sep. 19, 2024 and entitled “METHOD AND APPARATUS FOR WIRELESS POWER TRANSFER WITH RESONANT CAPACITOR SWITCHING,” which is hereby incorporated by reference herein as if reproduced in its entirety.

### TECHNICAL FIELD

The present disclosure relates generally to the wireless power transfer, and in particular embodiments, to techniques and mechanisms for wireless power transfer with resonant capacitor switching.

### BACKGROUND

As technologies further advance, wireless power transfer has emerged as an efficient and convenient mechanism for powering or charging battery based electronic devices such as mobile phones, smart phones, smart watches, laptops, digital cameras, MP3 players, tablets, e-readers, handheld gaming consoles, and/or the like. A wireless power transfer system typically includes a primary side transmitter and a secondary side receiver. The primary side transmitter is magnetically coupled to the secondary side receiver through magnetic coupling. The magnetic coupling may be implemented as a loosely coupled transformer having a primary side coil formed in the primary side transmitter and a secondary side coil formed in the secondary side receiver.

The primary side transmitter may include a power conversion unit such as a primary side power converter. The power conversion unit is coupled to a power source and is capable of converting electrical power to wireless power signals. The secondary side receiver is able to receive the wireless power signals through the loosely coupled transformer and convert the received wireless power signals to electrical power suitable for a load.

### SUMMARY

Technical advantages are generally achieved, by embodiments of this disclosure which describe method and apparatus for wireless power transfer with resonant capacitor switching.

In accordance with one aspect of the present disclosure, an apparatus for wireless power transfer is provided that includes: a resonant circuit comprising: a transmitter coil; a first capacitor connected with the transmitter coil in series; and a second capacitor connected in series with a first switch, wherein the second capacitor and the first switch are connected in parallel with the first capacitor; and a control circuit connected to the resonant circuit and configured to: detect whether an event of a voltage across the first capacitor or a current of the transmitter coil occurs; and when detecting that the event occurs, control to turn on the first switch in response to a signaling of turning on the first switch.

In accordance with another aspect of the present disclosure, a method applied to a wireless power transmitter is provided. The wireless power transmitter comprises: a first capacitor and a transmitter coil connected in series; and a second capacitor connected in series with a first switch, wherein the second capacitor and the first switch are connected in parallel with the first capacitor. The method includes: detecting whether an event of a voltage across the first capacitor or a current of the transmitter coil occurs; and when the event occurs, controlling to turn on the first switch in response to a signaling of turning on the first switch.

In accordance with another aspect of the present disclosure, an apparatus for wireless power transfer is provided that includes a resonant circuit which includes: a transmitter coil; a first capacitor connected with the transmitter coil in series; and a second capacitor connected in series with a first switch, wherein the second capacitor and the first switch are connected in parallel with the first capacitor. The apparatus further includes a detection circuit configured to detect a voltage across the first capacitor or a current of the transmitter coil; and a control circuit connected to the detection circuit. The control circuit is configured to: determine that the voltage across the first capacitor or the current of the transmitter coil satisfies a predetermined condition, and based thereon, control to turn on the first switch in response to receipt of a signaling of turning on the first switch.

In accordance with another aspect of the present disclosure, a controller is provided that includes a circuit configured to: detect a voltage across a first capacitor of a capacitor bank or a current of a transmitter coil, wherein the capacitor bank is connected with the transmitter coil in series, and the capacitor bank further comprises a second capacitor connected in series with a first switch, with the second capacitor and the first switch being connected in parallel with the first capacitor; determine whether the voltage across the first capacitor or the current of the transmitter coil satisfies a predetermined condition; and when the voltage across the first capacitor or the current of the transmitter coil satisfies the predetermined condition, control to turn on the first switch in response to receipt of a signaling of turning on the first switch.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a diagram of an example wireless power transfer system according to embodiments of the present disclosure;

FIG. 2 is a diagram of an example circuit of a power transmitter in a wireless power transfer system according to embodiments of the present disclosure;

FIG. 3 is a diagram showing example switches that may be used to implement embodiments of the present disclosure;

FIG. 4 is a flowchart of an example method for switching control of a capacitor bank in a power transmitter according to embodiments of the present disclosure;

FIG. 5 is a diagram of an example control circuit for a power transfer system according to embodiments of the present disclosure;

FIG. 6 is a diagram of an example circuit at the transmitter side of a power transfer system according to embodiments of the present disclosure;

FIG. 7 is a diagram showing example waveforms of the circuit in FIG. 6 according to embodiments of the present disclosure;

FIG. 8 is a diagram of another example circuit at the transmitter side of a power transfer system according to embodiments of the present disclosure;

FIG. 9 is a flowchart of another example method for switching control of a capacitor bank in a power transmitter according to embodiments of the present disclosure;

FIG. 10 is a flowchart of yet another example method for switching control of a capacitor bank in a power transmitter according to embodiments of the present disclosure; and

FIG. 11 is a flowchart of yet another example method for switching control of a capacitor bank in a power transmitter according to embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Further, one or more features from one or more of the following described embodiments may be combined or used to create alternative embodiments not explicitly described, and features suitable for embodiments are understood to be within the scope of this disclosure. It is therefore intended that the appended claims encompass any such modifications or embodiments.

The present disclosure will be described with respect to embodiments in a specific context, namely, a method and apparatus for wireless power transfer with resonant capacitor switching. The disclosure may also be applied, however, to a variety of power systems. Hereinafter, various embodiments will be explained in detail with reference to the accompanying drawings.

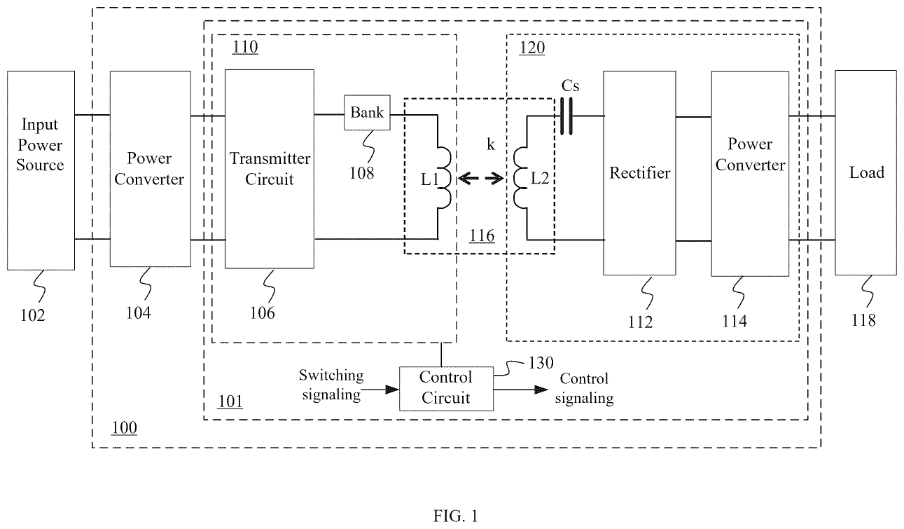

FIG. 1 is a diagram of an example wireless power transfer system 100 according to embodiments of the present disclosure. The wireless power transfer system 100 may include a power converter 104 and a wireless power transfer device 101 connected in cascade between an input power source 102 and a load 118. In some embodiments, the power converter 104 is employed to further improve the performance of the wireless power transfer system 100. In other embodiments, the power converter 104 is an optional element. In other words, the wireless power transfer device 101 may be connected to the input power source 102 directly.

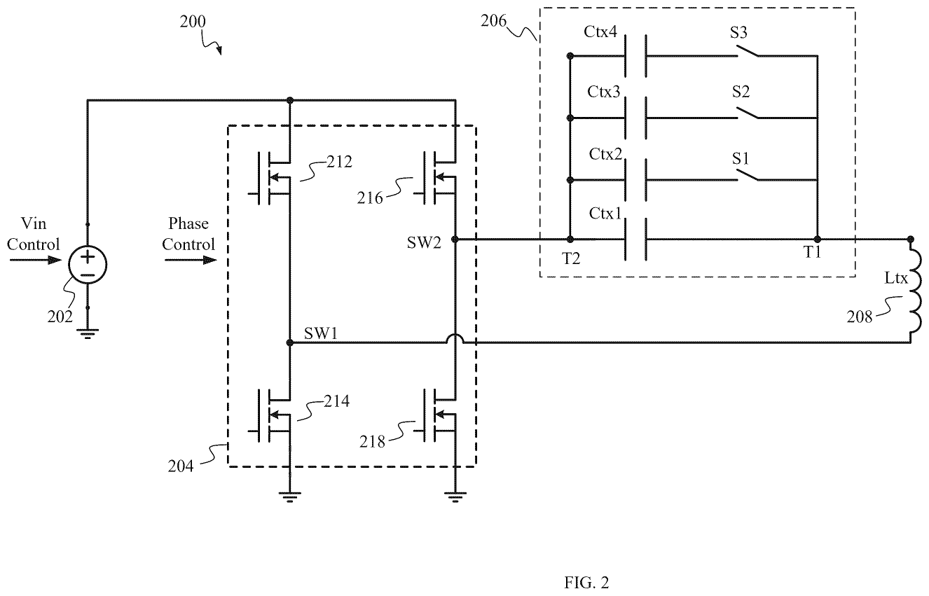

The wireless power transfer device 101 includes a power transmitter 110 (which is also referred to as a transmitter in the present disclosure) and a power receiver 120 (which is also referred to as a receiver in the present disclosure). As shown in FIG. 1, the power transmitter 110 includes a transmitter circuit 106, a resonant capacitor bank (which is also referred to as capacitor bank or bank) 108, and a transmitter coil L1. The resonant capacitor bank 108 and the transmitter coil L1 are connected in series, and may form a resonant tank (or resonant circuit) at the transmitter side. In an embodiment, the capacitor bank 108 may include multiple capacitors connected in parallel, where two or more capacitors may be connected to the transmitter coil L1 through a switch. An example of the capacitor bank 108 is provided in FIG. 2, which shows a capacitor bank 206. By selectively switch in and out a capacitor in the capacitor bank, the resonant capacitance at the transmitter side may be dynamically controlled during power transfer of the power transfer system 100. This improves wireless power transfer efficiency, and allows to maintain a suitable gain of output in a power transfer system, e.g., in a 25 W magnetic power profile (MPP) system.

Depending on design needs and different applications, the transmitter side resonant tank may further include a resonant inductor. In some embodiments, the resonant inductor may be implemented as an external inductor. In other embodiments, the resonant inductor may be implemented as a connection wire. The transmitter circuit 106 and the resonant tank are connected in cascade. The input of the transmitter circuit 106 is coupled to an output of the power converter 104. A first output terminal of the transmitter circuit 106 is connected to a first terminal of the capacitor bank 108. A second output terminal of the transmitter circuit 106 is connected to a second terminal of the capacitor bank 108 through the transmitter coil L1.

The power receiver 120 may include a receiver coil L2, a resonant capacitor Cs, a rectifier 112 and a power converter 114 connected in cascade. As shown in FIG. 1, the resonant capacitor Cs is connected in series with the receiver coil L2 and further connected to the inputs of the rectifier 112. The resonant capacitor Cs may also be referred to as a receiver resonant capacitor or a secondary resonant capacitor. The resonant capacitor Cs may help achieve soft switching for the wireless power transfer system 100. The outputs of the rectifier 112 are connected to the inputs of the power converter 114. The outputs of the power converter 114 are coupled to the load 118.

The power transmitter 110 is magnetically coupled to the power receiver 120 through a magnetic field when the power receiver 120 is placed near the power transmitter 110. A loosely coupled transformer 116 is formed by the transmitter coil L1, which is part of the power transmitter 110, and the receiver coil L2, which is part of the power receiver 120. As a result, electrical power may be transferred from the power transmitter 110 to the power receiver 120.

In some embodiments, the power transmitter 110 may be inside a charging pad. The transmitter coil L1 is placed underneath the top surface of the charging pad. The power receiver 120 may be embedded in an electronic device to be wirelessly charged, e.g., a mobile device, such as a smart phone, a tablet, a smart watch, an e-reader, a laptop, a gaming console, etc. When the electronic device is placed near the charging pad, a magnetic coupling may be established between the transmitter coil L1 and the receiver coil L2. In other words, the transmitter coil L1 and the receiver coil L2 may form a loosely coupled transformer through which a power transfer occurs between the power transmitter 110 and the power receiver 120. The strength of coupling between the transmitter coil L1 and the receiver coil L2 is quantified by a coupling coefficient k. In some embodiments, k is in a range from about 0.05 to about 0.9.

In some embodiments, after the magnetic coupling has been established between the transmitter coil L1 and the receiver coil L2, the power transmitter 110 and the power receiver 120 may form a power system through which power is wirelessly transferred from the input power source 102 to the load 118.

The input power source 102 may be a power adapter converting a utility line voltage to a direct-current (DC) voltage. The input power source 102 may also be a renewable power source such as a solar panel array. The input power source 102 may be any suitable energy storage devices such as rechargeable batteries, fuel cells, any combination thereof and/or the like.

The load 118 represents the power consumed by the electronic device coupled to the power receiver 120. As an example, the load 118 may also be a rechargeable battery and/or batteries connected in series/parallel, and coupled to the output of the power receiver 120. As another example, the load 118 may be a downstream power converter such as a battery charger.

The transmitter circuit 106 may include primary side switches of a full-bridge converter according to some embodiments. The transmitter circuit 106 may include primary side switches of any other suitable power converters, such as a half-bridge converter, a push-pull converter, any combinations thereof and/or the like.

It should be noted that the power converters described above are merely examples. One of ordinary skill in the art would recognize that other suitable power converters, such as class E topology based power converters (e.g., a class E amplifier), may be used depending on design needs and different applications.

The power receiver 120 includes the receiver coil L2 that is magnetically coupled to the transmitter coil L1 after the power receiver 120 is placed near the power transmitter 110. As a result, power may be transferred to the receiver coil L2 and further delivered to the load 118 through the rectifier 112. The power receiver 120 may further include a communication apparatus (not shown) connected between inputs of the rectifier 112 and ground. The communication apparatus is configured to transmit control signals from the receiver 120 to the transmitter 110. As an example, the communication apparatus may be configured to transmit the control signals through suitable modulation schemes such as amplitude shift keying (ASK). The ASK modulation scheme may be implemented by adjusting the impedance coupled to the receiver coil L2. As a result of adjusting the impedance coupled to the receiver coil L2, the gain of the wireless power transfer system 100 varies accordingly. The transmitter 110 detects the variation of the gain through analyzing the current flowing through the transmitter coil L1 and/or the voltage across the transmitter coil L1. The variation of the gain can be demodulated to retrieve the control signals sent from the receiver.

The rectifier 112 converts an alternating polarity waveform received from the resonant tank comprising the receiver coil L2 and the receiver resonant capacitor Cs to a single polarity waveform. In some embodiments, the rectifier 112 may include a full-wave diode bridge and an output capacitor. In some other embodiments, the full-wave diode bridge may be replaced by a full-wave bridge formed by switching elements such as n-type metal oxide semiconductor (NMOS) transistors.

Furthermore, the rectifier 112 may be formed by other types of controllable devices such as metal oxide semiconductor field effect transistor (MOSFET) devices, bipolar junction transistor (BJT) devices, super junction transistor (SJT) devices, insulated gate bipolar transistor (IGBT) devices, gallium nitride (GaN) based power devices and/or the like. The detailed operation and structure of the rectifier 112 are well known in the art, and hence are not discussed herein.

The power converter 114 is coupled between the rectifier 112 and the load 118. Those of ordinary skill in the art would understand that the following description about the power converter 114 at the receiver side may be similarly applied to the power converter 104 at the transmitter side, and the power converter 104 may be implemented similarly depending on needs and applications at the transmitter side. The power converter 114 may be employed to further adjust the voltage/current applied to the load 118. The power converter 114 may be a non-isolated power converter. In some embodiments, the power converter 114 may be implemented as a step-down power converter such as a buck converter. In some other embodiments, the power converter 114 may be implemented as a four-switch buck-boost power converter.

Furthermore, the power converter 114 may be implemented as a hybrid power converter. The hybrid converter is a non-isolated power converter. By controlling the on/off of the switches of the hybrid converter, the hybrid converter may be configured as a buck converter, a charge pump converter or a hybrid converter.

Depending design needs and different applications, the hybrid converter may operate in different operating modes. Particularly, the hybrid converter may operate in a buck mode when the load current is less than a predetermined current threshold and/or the input voltage is less than a predetermined voltage threshold. In the buck mode, the hybrid converter is configured as a buck converter. The hybrid converter may operate in a charge pump mode or a hybrid mode when the input voltage is greater than the predetermined voltage threshold and/or the load current is greater than the predetermined current threshold. Particularly, in some embodiments, the hybrid converter may operate in a charge pump mode or a hybrid mode when a ratio of the output voltage of the hybrid converter to the input voltage of the hybrid converter is less than 0.5. In the charge pump mode, the hybrid converter is configured as a charge pump converter. In the hybrid mode, the hybrid converter is configured as a hybrid converter.

In some embodiments, the hybrid converter includes a first switch, a capacitor and a second switch connected in series between the output of the rectifier 112 and the input of the load 118. The hybrid converter further includes a third switch and a fourth switch. The third switch is connected between a common node of the first switch and the capacitor, and a common node of the second switch and the output terminal of the hybrid converter. The fourth switch is connected between a common node of the capacitor and the second switch, and ground.

Moreover, the power converter 114 may include a first power stage and a second power stage connected in cascade. The first power stage is configured to operate in different modes for efficiently charging the load 118 (e.g., a rechargeable battery). In some embodiments, the first stage may be implemented as a step-down power converter (e.g., a buck converter), a four-switch buck-boost converter, a hybrid converter and any combination thereof. The second power stage is configured as a voltage divider or an isolation switch.

In some embodiments, the wireless power transfer device 101 may include a control circuit 130 connected to the power transmitter 110. As an example, the control circuit 130 may be specifically connected to the resonant tank of the power transmitter 110. The control circuit 130 is configured to control to switch in and out a capacitor in the capacitor bank 108 in response to a switching signaling. The switching signaling may be a system command to turn on or off a switch in the capacitor bank in order to switch in or out a capacitor associated with the switch. The control circuit 130 may be configured to detect a parameter at the transmitter side, determine whether to switch in or out the capacitor based on the detected parameter, and generate a corresponding control signaling based on the determination result and the switching signaling. As an example, the control signaling may be an instruction/command indicating to turn on a switch by applying a drive signal. Further details will be provided in the following.

FIG. 2 is a diagram of an example circuit 200 of a power transmitter in a wireless power transfer system according to embodiments of the present disclosure. The circuit 200 may be used to implement the power transmitter 110 described with respect to FIG. 1. In this example, the circuit 200 includes a switch circuit 204, which may be used to implement the transmitter circuit 106 in FIG. 1, a capacitor bank 206, and a transmitter coil 208 (Ltx). As used herein, the capacitor bank may also be referred to as a bank. The switch circuit 204 includes power switches 212, 214, 216 and 218. As an example, the power switches may be implemented using MOSFETs. The power switches 212 and 214 are connected in series between an input power source 202 and a ground. The power switches 216 and 218 are connected in series between the input power source 202 and the ground. A common node between the power switches 212 and 214 is SW1. A common node between the power switches 216 and 218 is SW2. The voltage Vin of the input power source 202 may be controlled to vary depending on various needs and applications. The input power source 202 may be an output of a power converter, e.g., the power converter 104, an applicable energy storage device, or an applicable energy source.

The capacitor bank 206 is connected in series with the transmitter coil 208. The capacitor bank 206 in this example includes four capacitors, i.e., Ctx1, Ctx2, Ctx3 and Ctx4. The capacitor Ctx1 is connected with the transmitter coil 208 in series between the nodes SW1 and SW2. The capacitor Ctx2 is connected with a first switch S1 in series between two terminals T1 and T2 of the capacitor Ctx1. The capacitor Ctx3 is connected with a second switch S2 in series between the two terminals T1 and T2 of the capacitor Ctx1. The capacitor Ctx4 is connected with a third switch S3 in series between the two terminals T1 and T2 of the capacitor Ctx1. That is, Ctx1, Ctx2 and its associated switch S1, Ctx3 and its associated switch S2, and Ctx4 and its associated switch S3 are connected in parallel with each other between the nodes T1 and T2. FIG. 2 shows four capacitors included in the capacitor bank 206 merely for illustration purposes, and various numbers of capacitors, e.g., 2, 3, 5, or 6 capacitors, may be included in the capacitor bank 206, depending on design needs and applications. As an example, the capacitors Ctx1-Ctx4 may have respective capacitances of 68 nano Farads (nF), 33 nF, 390 nF and 33 nF.

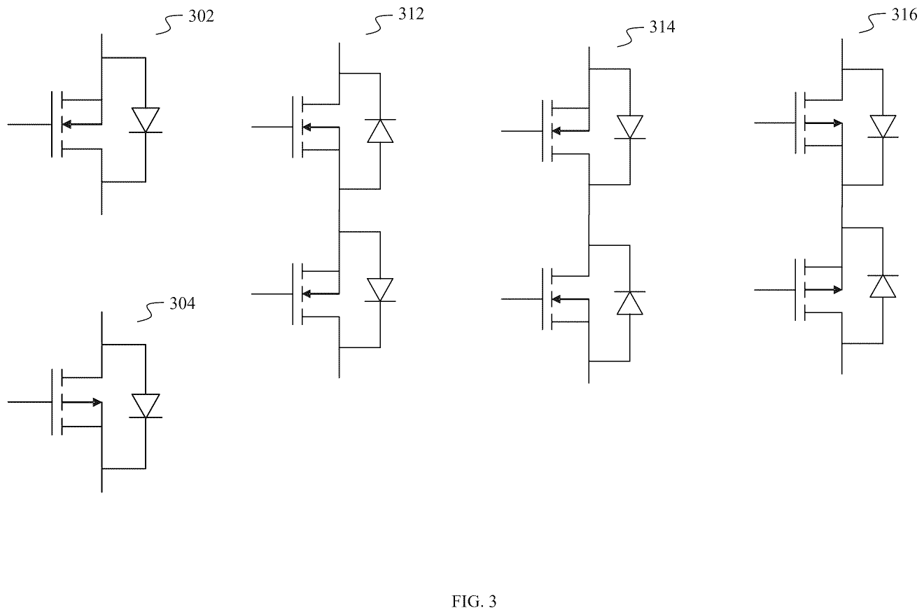

The switches S1-S3 each may be implemented as a single switch or a back-to-back switch, and may be implemented using field effect transistors (FETs). FIG. 3 is a diagram showing example switches that may be used to implement the switches S1-S3 according to embodiments of the present disclosure. Switch 302 is an example N-type switch including a N-MOSFET and a body diode. Switch 304 is an example P-type switch including a P-MOSFET and a body diode. Switch 312 is an example back-to-back switch including two N-MOSFETs with their sources connected directly to each other. Switch 314 is an example back-to-back switch including two N-MOSFETs with their drains connected directly to each other. Switch 316 is an example back-to-back switch including two P-MOSFETs with their sources connected directly to each other. The structures and operations of the switches are well known in the art, and details will be omitted herein.

The power transfer system may be configured to switch in or out one or more of the capacitors Ctx2, Ctx3 and Ctx4 during power transfer of the power transfer system. By selectively switching in or out a capacitor at the power transmitter side, the power transmitter provides a resonant capacitance of the capacitor bank 206 that can be dynamically adjusted, to accommodate scenarios of different load requirements and/or different coupling strengths of the transformer, which allows the power transfer system to maintain a suitable gain of the system output and obtain a desirable wireless charging efficiency.

The power transfer system may determine whether to switch in or out one of the capacitors Ctx2-Ctx4, e.g., based on a power requirement of a load and/or the coupling strength of the transformer. As an example, in a scenario of a high-power load and the coupling coefficient K>0.81*α, the power transfer system may select to switch in the capacitor Ctx3 to provide a resonant capacitance 458 nF. The power transfer system may send out a switching command/signaling triggering to turn on or off the switch S2 associated with the capacitor Ctx3. A drive voltage may be applied to the switch S2 to turn on the switch S2 during power transfer of the power transfer system, thereby switching in the capacitor Ctx3 in the resonant tank at the transmitter side. The switching command/signaling may instruct to switch in one or more capacitors in the capacitor bank.

Switching in a capacitor during power transfer of the power transfer system may cause stress on devices (e.g., the switches) of the resonant tank. For example, one issue that may arise during switching-in is that a surge current may be generated flowing through the switch that is being turned on such as the switch S2, and the surge current may be large, which may cause huge transient power loss, and damage the switch. The issue may generally be caused by the large difference between the voltage across the capacitor Ctx1 and the voltage across the capacitor being switched in. As an example, if the switch S2 is turned on to switch in the capacitor Ctx3 when the voltage across the capacitor Ctx1 is zero-crossing or is near zero and the voltage across the capacitor Ctx3 is at about the input voltage Vin, a large surge current may be generated flowing through the switch S2, causing stress on the switch S2.

To mitigate or avoid such stress, in some embodiments, a control circuit (or a controller), such as the control circuit 130 as shown in FIG. 1, may be provided to further control switching-in of a capacitor of the capacitor bank when a command (or signaling) is received to turn on an associated switch of the capacitor (to-be-switched-in capacitor). Specifically, the control circuit may control whether or when to switch in the capacitor when the command is received. As an example, it would be desirable to switch in the capacitor when the difference between the voltage across the capacitor Ctx1 and the voltage across the to-be-switched-in capacitor is zero or less than a threshold, in order to reduce the stress on the switch of the to-be-switched-in capacitor while the switch is turned on during operation of the power transfer system.

Various embodiments are described in the following, taking as an example that the command instructs to turn on the switch S2 in order to switch in the capacitor Ctx3. These embodiments may be similarly applied for switching in other capacitors of the capacitor bank.

In some embodiments, when the command is received, the control circuit may control to switch in the capacitor Ctx3 (e.g., completely turning on the switch S2) when a predetermined event occurs. The event may be determined based on one or more parameters of the power transmitter, such as the voltage across the capacitor Ctx1, or the current flowing through the transmitter coil Ltx 208. Other applicable parameters may also be used to define the event if they are detectable and usable to determine whether a capacitor of the capacitor bank can be switched in with tolerable/acceptable surge current produced. The embodiment approach where whether to switch in a capacitor is determined based on whether a predetermined event occurs is referred to as event-based switching. A power transmitter may operate in an event-based switching mode when enabled.

The event may occur when one or more parameters satisfy a predetermined condition, examples of which are provided in the following with reference to FIG. 2.

In one embodiment, when the command is received, the control circuit may control to switch in the capacitor Ctx3 when the voltage across the capacitor Ctx1 reaches a peak voltage of the capacitor Ctx1. In another embodiment, when the command is received, the control circuit may control to switch in the capacitor Ctx3 when the voltage across the capacitor Ctx1 is greater than a voltage threshold. The voltage threshold may be determined based on the peak voltage of the capacitor Ctx1 depending on design needs or applications of the power transfer system. For example, the voltage threshold may be set to 80%, 90% or 95% of the peak voltage of the capacitor Ctx1.

In yet another embodiment, when the command is received, the control circuit may control to switch in the capacitor Ctx3 when the current flowing through the transmitter coil 208 of the power transmitter, crosses zero (0) (i.e., is zero-crossing). In yet another embodiment, when the command is received, the control circuit may control to switch in the capacitor Ctx3 when the current flowing through the transmitter circuit 204 (bridge current), e.g., the current through the switch 212, 214, 216 or 218, crosses zero (0) (i.e., is zero-crossing). The current flowing through the transmitter circuit 204 is the same as the current flowing through the transmitter coil of the power transmitter. In yet another embodiment, when the command is received, the control circuit may control to switch in the capacitor Ctx3 when the current flowing through the transmitter coil (or the bridge current) is less than a current threshold. The current threshold may be determined based on the peak current of the transmitter coil Ltx depending on design needs or applications of the power transfer system. For example, the current threshold may be set to 1%, 5% or 10% of the peak current of the transmitter coil Ltx.

When the switch S2 is a back-to-back switch, the following embodiments may be provided.

In one embodiment, when the command is received, the control circuit may control to switch in the capacitor Ctx3 when the voltage across the capacitor Ctx1 crosses zero (0) (i.e., zero-crossing). In another embodiment, when the command is received, the control circuit may control to switch in the capacitor Ctx3 when the voltage across the capacitor Ctx1 is less than a voltage threshold. The voltage threshold may be determined based on the peak voltage of the capacitor Ctx1 depending on design needs or applications of the power transfer system. For example, the voltage threshold may be set to 1%, 5% or 10% of the peak voltage of the capacitor Ctx1.

In yet another embodiment, when the command is received, the control circuit may control to switch in the capacitor Ctx3 when the current flowing through the transmitter coil of the power transmitter (or the bridge current) reaches a peak current of the transmitter coil. In yet another embodiment, when the command is received, the control circuit may control to switch in the capacitor Ctx3 when the current flowing through the transmitter coil (or the bridge current) is greater than a current threshold. The current threshold may be determined based on the peak current of the transmitter coil depending on design needs or applications of the power transfer system. For example, the current threshold may be set to 80%, 95% or 98% of the peak current of the transmitter coil Ltx.

In some embodiments, when the command is received, the control circuit may control to switch in the capacitor Ctx3 when the difference between the voltage across the capacitor Ctx1 and the voltage across the to-be-switched-in capacitor is less than a voltage threshold. The voltage threshold may be determined based on the tolerance of the power transfer system to the amount of the surge current caused by switching in the capacitor, and/or required power transfer efficiency.

In some embodiments, the control circuit may control the drive speed of turning on a switch such as S2, to slowly or gradually turn on the switch in order to avoid generating large surge current. Taking as an example where the switch S2 is implemented using a FET, depending on the gate drive voltage, the FET may operate in one of at least three modes: an on-mode where the FET functions as a switch that is turned on completely, a cut-off mode where the FET functions as a switch that is turned off, and an ohmic mode where the FET functions as a switch with an on-resistance that is variable and controllable by the gate drive voltage. In some embodiments, by varying the gate drive voltage under the control of the control circuit, the switch S2 may be driven to present various on-resistances that allow the current flowing through the switch S2 to increase at a predetermined rate or in a predetermined pattern. This embodiment approach may be referred to as drive-based switching. A power transmitter may operate in a drive-based switching mode when enabled. A power transmitter may perform the drive-based switching no matter whether the event-based switching is enabled or not.

As an example, when determining to switch in the capacitor Ctx3, the control circuit may control to turn on the switch S2 initially at a first drive voltage for a first time interval, where the first drive voltage causes the switch S2 to have a first on-resistance that limits the current flowing through the switch S2 to a first current I1. The first drive voltage may be set such that first current I1 is small and won't cause any stress on the switch S2 being turned on. For the next time interval (a second time interval), the control circuit may then control to change the gate drive voltage of the switch S2 to a second drive voltage, which causes the switch S2 to have a second on-resistance smaller than the first on-resistance. The second on-resistance limits the current flowing through the switch S2 to a second current I2 greater than the first current I1. The control circuit may then control to change the drive voltage of the switch S2 for the next time interval (a third time interval) similarly, to allow the current flowing through the switch S2 to increase (e.g., greater than the second current I2), and so on.

In an embodiment, the control circuit may continue to control to change the drive voltage of the switch S2 until the current flowing through the switch S2 reaches a threshold level, or until the switch S2 is completely turned on. In another embodiment, each time before changing the drive voltage of the switch S2 for the next time interval, the control circuit may detect whether the difference between the voltage across the capacitor Ctx1 and the voltage across the capacitor Ctx3 is less than a voltage threshold. If the difference is less than the voltage threshold, the control circuit may control to turn on the switch S2 completely. If the difference is not less than the voltage threshold, the control circuit may control to change the drive voltage of the switch S2 for the next time interval to increase the current flowing through the switch S2, as described previously.

The lengths of the time intervals may be the same or different. The lengths of the time intervals, the number of the time intervals used, i.e., the number of different drive voltages used to vary the on-resistances of the switch, the differences between the drive voltages used in the time intervals, and/or the incremental amounts of the current (the current increasing rate), may be predetermined and configurable depending on various design needs and practical applications. A principle is that these parameters are selected/determined to avoid or reduce the stress on the switch S2 caused by turning on the switch while the power transmitter is operating to transfer power.

In the above examples, when operating in the drive-based switching mode, the control circuit may control to sequentially apply a set of drive voltages to the switch S2 so that the switch S2 has a set of corresponding on-resistances, which enable the current flowing through the switch S2 to increase gradually, thereby avoiding generating large surge current when turning on the switch S2.

In some embodiments, when determining to turn on the switch S2, the control circuit may control to turn on the switch S2 at a predetermined drive voltage, which causes the switch S2 to have an on-resistance that limits the current flowing through the switch S2 below a current threshold. The current threshold may be determined in consideration of the tolerance of the switch S2 to the surge current, power transfer efficiency, allowable power loss, or other applicable factors. In one embodiment, the switch S2 may be controlled to stay in this on-state driven by the predetermined drive voltage until it is turned off, e.g., in response to a command to turn off the switch S2. In another embodiment, after the switch S2 is turned on at the predetermined drive voltage, the control circuit may continuously or periodically detect whether the difference between the voltage across the capacitor Ctx1 and the voltage across the capacitor Ctx3 is less than a voltage threshold. If the difference is less than the voltage threshold, the control circuit may control to turn on the switch S2 completely. If the difference is not less than the voltage threshold, the control circuit may control to keep the switch S3 on by the predetermined drive voltage.

In a power transmitter, one of the event-based switching mode and the drive-based switching mode, or both of the two modes may be enabled. Whether a mode is enabled or not for the power transmitter may be predetermined and configurable.

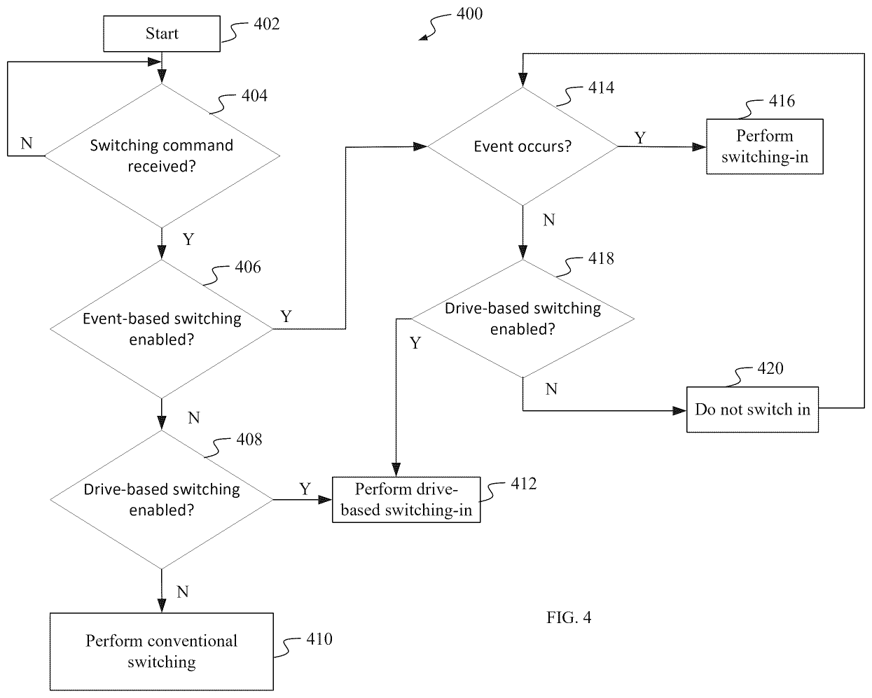

FIG. 4 is a flowchart of an example method 400 for switching control of a capacitor bank in a power transmitter according to embodiments of the present disclosure. The method 400 may be performed by a controller/processor (which include an embodiment control circuit) of a power transfer system. By use of the method 400, the power transfer system may perform capacitor bank switching according to embodiments of the present disclosure, or fall back to the conventional switching. One or more switching modes may be configured/enabled for the power transfer system.

The method 400 starts at step 402 and proceeds to step 404 to determine whether a switching command to switch in a capacitor is received. If no switching command is received, the method 400 continues to monitor a switching command (step 404). If the switching command is received, the method 400 proceeds to step 406 to determine whether the event-based switching mode is enabled. If the event-based switching mode is not enabled, the method 400 may determine whether the drive-based switching mode is enabled at step 408. If the drive-based switching mode is not enabled, the method 400 may perform the conventional switching at step 410, where the control circuit controls to turn on the associated switch of the to-be-switched-in capacitor at a drive voltage in response to receipt of the switching command.

If the drive-based switching mode is enabled, the method 400 proceeds to perform the drive-based switching at step 412 as described above. As an example, the control circuit may control to turn on the switch by applying various drive voltages to the switch to cause the switch to present various on-resistances, such that the current flowing through the switch increases gradually or at a predetermined rate. The control circuit may keep varying the drive voltage until the current flowing through the switch increases to reach a threshold, or until the switch is completely turned on. As another example, the control circuit may control to turn on the switch at a predetermined drive voltage which limits the current flowing through the switch to be less than a current threshold to avoid generating a large surge current. As another example, the control circuit may control to turn on the switch at a predetermined drive voltage to allow a small current flowing through the switch, and completely turn on the switch when the difference between the voltage across the capacitor Ctx1 and the voltage across the to-be-switched-in capacitor is less than a voltage threshold.

If the event-based switching mode is enabled, the method 400 may proceed to step 414 to detect whether an event occurs. As described above, in the case that the switch is implemented as a single switch, the event occurs when the voltage across the capacitor Ctx1 is greater than or equal to a threshold, which may be or may be determined based on a peak voltage of the capacitor Ctx1; or when the current through the transmitter coil Ltx is zero-crossing or less than a threshold. In the case that the switch is implemented as a back-to-back switch, the event occurs when the voltage across the capacitor Ctx1 is zero-crossing or less than a threshold; or when the current through the transmitter coil Ltx is greater than or equal to a threshold, which may be or may be determined based on a peak current of the transmitter coil Ltx. If the event occurs, the method 400 proceeds to step 416 to switch in the capacitor by completely turn on the switch. Which event is to be used for the event-based switching mode may be preconfigured with the controller, and configurable by the controller.

If the event does not occur, the method 400 may proceed to determine whether the drive-based switching mode is enabled at step 418. If the drive-based switching mode is enabled, the method 400 may proceed to step 412 to perform the drive-based switching as described above. If the drive-based switching mode is not enabled, the control circuit may control to not switch in the capacitor at step 420. In this case, the method 400 may proceed to step 414, where the control circuit may continue monitor whether an event occurs, and based thereon, determine whether to switch in the capacitor.

While the method 400 is described above with those steps as shown in FIG. 4, those of ordinary skill in the art would recognize that one or more of the steps may be removed, and/or optionally, and the steps may be re-ordered, depending on the mode that a power transmitter operates at. As an example, when a power transmitter is preconfigured with the event-based switching mode, the steps of 406-412 and 418 may be removed. In this case, the method 400 switches in the capacitor when the event occurs. As another example, when a power transmitter is preconfigured with the event-based switching mode and the drive-based switching mode, the steps of 406-410 and steps 418, 420 may be removed. In this case, when detecting that the event does not occur, the method 400 may perform the drive-based switching. As yet another example, the step 420 may be optional. As yet another example, when a power transmitter is preconfigured with the drive-based switching mode, the method 400 may only perform steps 404 and 412.

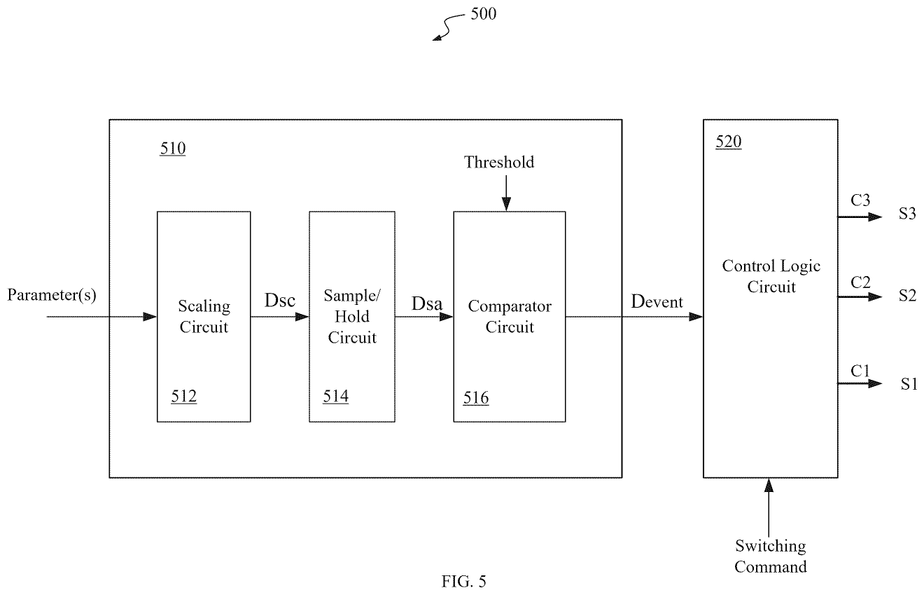

FIG. 5 is a diagram of an example control circuit 500 for a power transfer system according to embodiments of the present disclosure. FIG. 5 uses the power transmitter 200 as an example for illustration purpose only. The control circuit 500 may be applied when the event-based switching mode is enabled. As shown, the control circuit 500 includes a detection circuit 510 and a control logic circuit 520. The detection circuit 510 is configured to receive parameter(s) of a power transmitter, detect whether an event occurs based on the parameter(s), and output a signal Dₑᵥₑₙₜ indicating whether the event occurs. The output signal Dₑᵥₑₙₜ may be a logic signal indicating that the event occurs or not. For example, the signal Dₑᵥₑₙₜ may be a logic high signal (1) indicating occurrence of the event, or a logic low signal (0) indicating that the event does not occur.

The control logic circuit 520 may be configured to generate control signals C1, C2, C3 to control turning on/off the switches S1-S2, based on the signal Dₑᵥₑₙₜ and the switching command to turn on/off a switch for switching in a corresponding capacitor. A control signal C1, C2 or C3 may be a logic high signal (1) indicating to turn on a switch, or a logic low signal (0) indicating to turn off a switch. Those of ordinary skill in the art would recognize that other configurations for the signal Dₑᵥₑₙₜ and the control signals C1, C2, C3 may also be applicable. For example, the signal may be a logic low signal indicating that an event occurs, or a logic high signal indicating that the an event does not occur.

Taking the capacitor Ctx3/switch S2 as an example, when the switching command of switching in the capacitor Ctx3 (i.e., turning on the associated switch S2) is received and an event occurs, the control logic circuit may generate the control signal C2 (e.g., logic high) triggering turning on of the switch S2. When no switching command is received or when the event does not occur, the control logic circuit may generate the control signal C2 (e.g., logic low) indicating to keep the switch S2 off, or indicating to perform drive-based switching if the drive-based switching mode is enabled. In an example, the control logic may be implemented using an AND gate, with the signal Dₑᵥₑₙₜ and the switching command received respectively at two input terminals (e.g., G1 and G2) of the AND gate, and the control signal C1, C2 or C3 output at the output terminal of the AND gate. When the switching command is present, the terminal G2 of the AND gate may receive a logic high signal, and when no switching command is present, the terminal G2 of the AND gate may receive a logic low signal.

The detection circuit 510 may include a scaling circuit 512, a sample/hold circuit 514 and a comparator circuit 516 connected in cascade. The scaling circuit 512 is configured to adjust/regulate (e.g., amplifying or reducing) the value of an input parameter to be in a range suitable for processing by the subsequent circuits, and generate an output signal Dsc having an adjusted value of the input parameter. The scaling circuit 512 may be optional. The sample/hold circuit 514 is configured to receive the signal Dsc, and sample the signal Dsc to generate an sampled value/signal of Dsa and hold the sampled value/signal Dsa, which is fed to the comparator circuit 516. The comparator circuit 516 is configured to compare the sampled value Dsa with a threshold to determine whether an event occurs, and based thereon, output the signal Dₑᵥₑₙₜ indicating the determination result.

Table 1 below provides 9 scenarios, including example parameters that can be used for detecting occurrence of events, corresponding events, and corresponding thresholds that may be used for the detection, taking the power transmitter 200 in FIG. 2 as an example. These scenarios have been discussed previously and details are not repeated. A controller of the power transmitter may be configured to detect one or more events to control switching of the capacitor bank in response to a switching command.

TABLE 1

| Scenario | Parameter | Event | Threshold |
|---|---|---|---|
| 1 | Voltage across Ctx1 | Reaches peak | Peak voltage of Ctx1 |
| | (single switch) | voltage of Ctx1 | |
| 2 | Current flowing through | Zero-crossing | 0 |
| | Ltx (single switch) | | |
| 3 | Voltage across Ctx1 | Greater than | A predetermined |
| | (single switch) | threshold | voltage based on the |
| | | | peak voltage of Ctx1 |
| 4 | Current flowing through | Less than | A predetermined |
| | Ltx (single switch) | threshold | current based on the |
| | | | peak current of Ltx |
| 5 | Voltage across Ctx1 | Zero-crossing | 0 |
| | (back-to-back switch) | | |
| 6 | Current flowing through | Reaches peak | Peak current of Ltx |
| | Ltx (back-to-back | current of Ltx | |
| | switch) | | |
| 7 | Voltage across Ctx1 | Less than | A predetermined |
| | (back-to-back switch) | threshold | voltage based on the |
| | | | peak voltage of Ctx1 |
| 8 | Current flowing through | Greater than | A predetermined |
| | Ltx (back-to-back | threshold | current based on the |
| | switch) | | peak current of Ltx |
| 9 | Voltage across Ctx1, and | Difference of the | Based on surge current |
| | voltage across the to-be- | voltages less than | tolerance, |
| | switched-in capacitor | the threshold | predetermined |

In some embodiments, when determining, e.g., using the method 400, that the event-based switching mode, the drive-based switching mode, or both are enabled for a power transmitter, the controller/processor may be configured to issue a control signal to connect the control circuit to the power transmitter, and the control circuit starts operating in the corresponding enabled mode(s). For example, a switch may be connected between the control circuit 130 and the power transmitter 100 in FIG. 1. The switch may be controlled to turn on in response to the control signal, and the control circuit starts receiving the parameter(s), detecting an event, and controlling the switching of the capacitor bank.

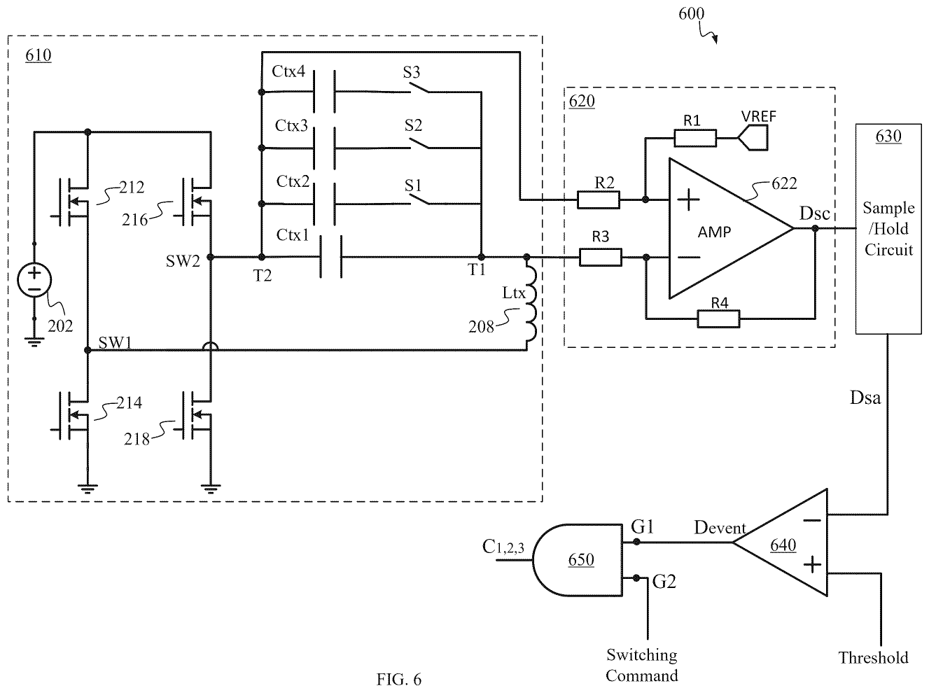

FIG. 6 is a diagram of an example circuit 600 at the transmitter side of a power transfer system according to embodiments of the present disclosure. The circuit 600 shows an example implementation of the control circuit 500, where the event-based switching mode is enabled. The circuit 600 includes a power transmitter 610 of the power transfer system, and a control circuit including a scaling circuit 620, a sample/hold circuit 630, a comparator 640, and an AND gate 650.

The power transmitter 610 is similar to the power transmitter 200, and thus details are not repeated herein. In this example, the circuit 600 is configured to detect an event of the voltage across the capacitor Ctx1, and based on the detection, determine whether to switch in a capacitor, e.g., Ctx3, in response to a switching command. The event of the voltage across the capacitor Ctx1 may include the example events shown in Table 1 above.

The scaling circuit 620 includes an amplifier 622, and resistors R1, R2, R3 and R4. The resistors R1 and R2 are connected in series between a reference voltage (VREF) and the node T2 of the power transmitter 610. A common node of the resistors R1 and R2 is connected to a first input terminal of the amplifier 622. The resistors R3 and R4 are connected in series between the output terminal of the amplifier 622 and the node T1 of the power transmitter 610. A common node of the resistors R3 and R4 is connected to a second input terminal of the amplifier 622. Thus, the first input terminal of the scaling circuit 620 receives a divided voltage of the voltage at the node T2 (i.e., one terminal of Ctx1), and the second terminal of the scaling circuit 620 receives a divided voltage of the voltage at the node T1 (i.e., the other terminal of Ctx1). In a case where VREF=0 and the resistors R1-R4 have the same resistance, the output signal Dsc of the scaling circuit 620 has a voltage about equal to V_{T2}−V_{T1}.

The sample/hold circuit 630 samples the output signal Dsc to generate a sample signal/voltage Dsa, which is fed to the comparator 640. The sample/hold circuit 630 may be implemented using various circuits conventionally known or any other applicable circuits. The comparator 640 compares the sampled signal Dsa with the threshold to determine whether an event occurs, and outputs a signal Dₑᵥₑₙₜ indicating the result of the comparison at its output terminal. In this case, the threshold may be any of those shown in Table 1. For example, the threshold may be the peak voltage of Ctx1, zero (0) in the case of back-to-back switch, or a voltage threshold predetermined. The output terminal of the comparator 640 is connected to a first input terminal G1 of the AND gate 650. A second input terminal G2 of the AND gate 650 is connected to the switching command signal. When the sampled signal Dsa satisfies the threshold, the output signal Dₑᵥₑₙₜ may be a logic high signal and fed to the terminal G1 of the AND gate. In response to the presence of the switching command at the terminal G2 (i.e., a logic high at G2), the AND gate 650 outputs a logic high signal C1,2,3, which may be used to trigger/control to turn on a to-be-switched-in capacitor, e.g., Ctx3 as indicated by the switching command. When the sampled signal Dsa does not satisfy the threshold, the AND gate 650 may output a logic low signal, which is used to control to turn off the switch or perform the drive-based switching if enabled.

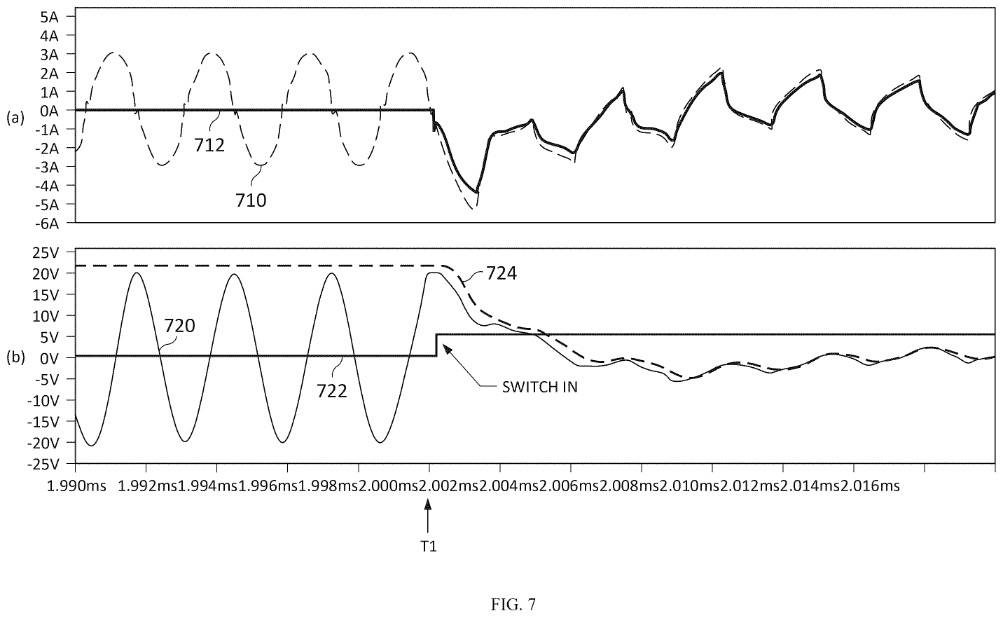

FIG. 7 is a diagram showing example waveforms of the circuit 600 according to embodiments of the present disclosure. In this example, the control circuit detects that the voltage across Ctx1 reaches its peak voltage, and controls to turn on the switch S2 in response to a switching command instructing to switch in the capacitor Ctx3. In diagram (a), the vertical axis represents current. In diagram (b), the vertical axis represents voltage. The horizontal axes of both diagrams represent time. Curve 710 represents the current flowing through the transmitter coil Ltx. Curve 712 represents the current flowing through the capacitor Ctx3. Curve 720 represents the voltage across the capacitor Ctx1. Curve 722 represents the drive voltage used to turn on the switch S2. Curve 724 represents the voltage across the capacitor Ctx3. The control circuit detects that the voltage across the capacitor Ctx1 reaches the peak voltage at time T1, and in response to receiving the switching command, the control circuit may generate a control signal controlling to apply the drive voltage to fully turn on the switch S2 soon after time T1. By use the event-based switching, the surge current can be greatly reduced.

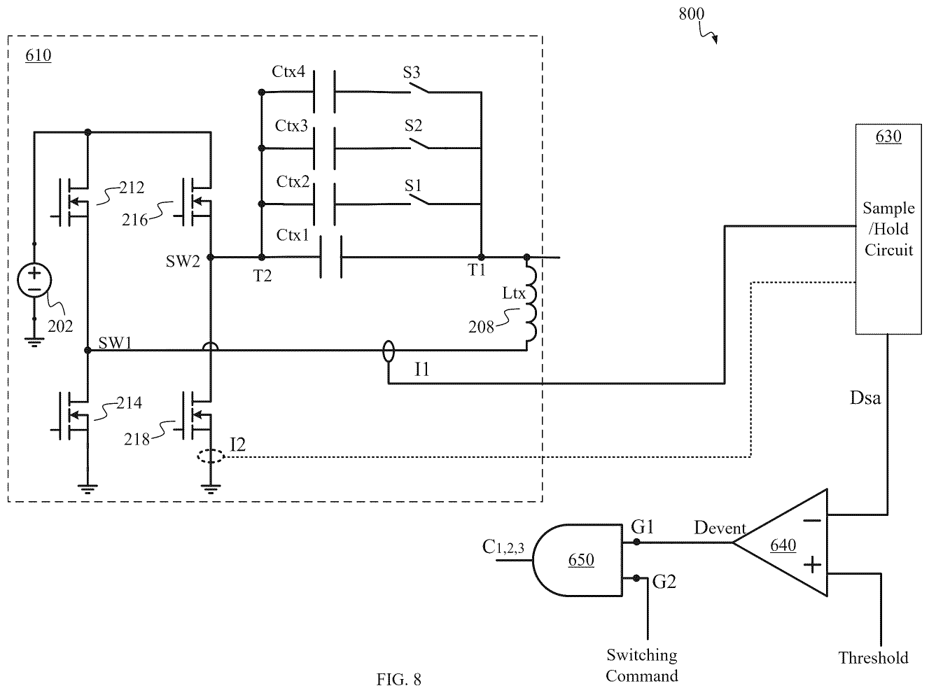

FIG. 8 is a diagram of yet another example circuit 800 at the transmitter side of a power transfer system according to embodiments of the present disclosure. The circuit 800 shows an example implementation of the control circuit 500, where the event-based switching mode is enabled. The circuit 800 includes the power transmitter 610 of the power transfer system, and a control circuit including the sample/hold circuit 630, the comparator 640, and the AND gate 650 as shown and described with respect to FIG. 6. The difference between the circuit 800 and the circuit 600 is that the circuit 800 does not include the scaling circuit, and the circuit 800 is configured to detect an event of the current flowing through the transmitter coil Ltx. The event of the current may include the example events shown in Table 1 above. Based on the detection result, the circuit 800 determines whether to switch in a capacitor, e.g., Ctx3, in response to a switching command.

As shown, in the example of FIG. 8, the sample/hold circuit 630 may be configured to sample the current I1 flowing through the transmitter coil Ltx to generate and hold a sampled signal/current Dsa, which is fed to the comparator 640. The comparator 640 compares the sampled signal Dsa with the threshold to determine whether an event occurs, and outputs a signal Dₑᵥₑₙₜ indicating the result of the comparison at its output terminal. In this case, the threshold may be any of those shown in Table 1. For example, the threshold may be the peak current of Ltx, zero (0) in the case of back-to-back switch, or a current threshold predetermined.

When the sampled signal Dsa satisfies the threshold, the output signal Dₑᵥₑₙₜ may be a logic high signal and fed to the terminal G1 of the AND gate. In response to the presence of the switching command at the terminal G2 (a logic high at G2), the AND gate 650 outputs a logic high signal C1,2,3, which may be used to trigger/control to turn on a to-be-switched-in capacitor, e.g., Ctx3 as indicated by the switching command. When the sampled signal Dsa does not satisfy the threshold, the AND gate 650 may output a logic low signal, which is used to control to turn off the switch or perform the drive-based switching if enabled.

Since I1 is the same as the current I2 flowing through a bridge of the transmitter circuit, the control circuit may also detect the current I2 in order to detect whether the event occurs.

In some embodiments, a power transfer system may include a control circuit that is a combination of the circuit 600 and the circuit 800. That is, the control circuit may be configured to detect an event of the voltage across Ctx1 and an event of the current flowing through the transmitter coil Ltx. For example, the control circuit may include a first control branch including the components 620, 630, 640 and 650 connected as shown in the circuit 600 for switching control based on detection of the event of the voltage across Ctx1, and a second control branch including the components 630, 640 and 650 connected as shown in the circuit 800 for switching control based on detection of the event of the current flowing through the transmitter coil Ltx.

In some embodiments, switching command(s) may be received instructing to switch in multiple switches. In this case, multiple AND gates may be provided, with each associated with one switch. Using FIG. 6 as an example, a switching command may instruct to switch in Ctx2 and Ctx3. The control signal Dₑᵥₑₙₜ may be fed to two AND gates respectively associated with the switches S1 and S2. Each AND gate may output a corresponding control signal based on the control signal Dₑᵥₑₙₜ and the switching command.

FIG. 6 and FIG. 8 provide example implementations of the control circuit for certain scenarios, e.g., several scenarios shown in Table 1, implementations for other scenarios may be readily achieved by those of ordinary skill in the art based on concept and principle of the present disclosure. Various alterations, modifications and changes may also be made to provide a control circuit configured to perform the event-based and the drive-based switching, without departing from the principle and spirit of the present disclosure.

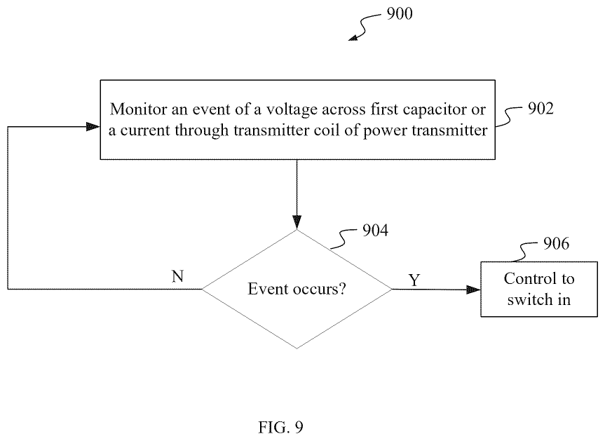

FIG. 9 is a flowchart of another example method 900 for switching control of a capacitor bank in a power transmitter according to embodiments of the present disclosure. The method 900 may be applied to the circuit 600 or the circuit 800, and may be performed by a control circuit as discussed above. As shown, at step 902, the control circuit may monitor an event of a voltage across a first capacitor (e.g., Ctx1) of a capacitor bank (e.g., the capacitor bank 206) or a current through a transmitter coil (e.g., Ltx) of a power transmitter (e.g., the power transmitter 200, or 610). The control circuit may determine whether the event occurs at step 904. When the event occurs, and in response to a switching command/signaling of switching in a capacitor (e.g., Ctx3), the control circuit controls to switch in the capacitor by controlling to completely/fully turn on the switch S2 associated with Ctx3 at step 906. When the event does not occur, the control circuit performs step 902 to continue to monitor the event. Step 902 may be performed continuously or periodically, or may be performed when the switching command is received.

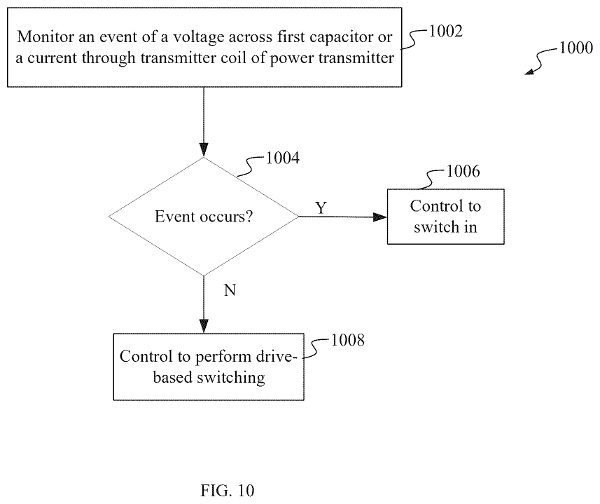

FIG. 10 is a flowchart of yet another example method 1000 for switching control of a capacitor bank in a power transmitter according to embodiments of the present disclosure. The method 1000 may be applied to the circuit 600 or the circuit 800, and may be performed by a control circuit as discussed above. As shown, at step 1002, the control circuit may monitor an event of a voltage across a first capacitor (e.g., Ctx1) of a capacitor bank (e.g., the capacitor bank 206) or a current through a transmitter coil (e.g., Ltx) of a power transmitter (e.g., the power transmitter 200, or 610). At step 1004, the control circuit may determine whether the event occurs. When the event occurs, and in response to a switching command/signaling of switching in a capacitor (e.g., Ctx3), the control circuit controls to switch in the capacitor Ctx3 by controlling to completely turn on the switch S2 associated with Ctx3 at step 1006. When the event does not occur, the control circuit performs step 1008 to control to perform the drive-based switching to turn on the switch S2. Step 1002 may be performed continuously or periodically, or may be performed when the switching command is received.

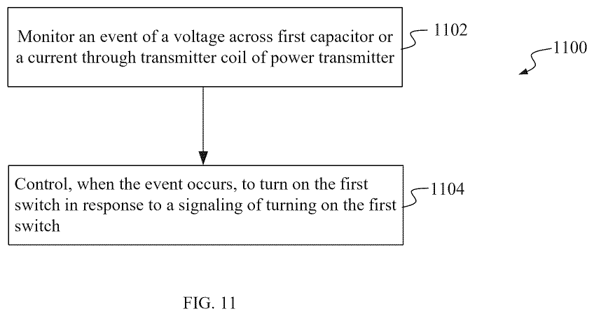

FIG. 11 is a flowchart of yet another example method 1100 for switching control of a capacitor bank in a power transmitter according to embodiments of the present disclosure. The method 1100 may be applied to the circuit 600 or the circuit 800, and may be performed by a control circuit as discussed above. As an example, the wireless power transmitter may include: a first capacitor and a transmitter coil connected in series; and a second capacitor connected in series with a first switch, where the second capacitor and the first switch are connected in parallel with the first capacitor. As shown, at step 1102, the control circuit may detect whether an event of a voltage across the first capacitor or a current of the transmitter coil occurs. At step 1104, when the event occurs, the control circuit may control to turn on the first switch in response to a signaling of turning on the first switch.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed:

1. An apparatus for wireless power transfer, comprising:
a resonant circuit, comprising:
a transmitter coil;
a first capacitor connected with the transmitter coil in series; and
a second capacitor connected in series with a first switch, wherein the second capacitor and the first switch are connected in parallel with the first capacitor; and
a control circuit connected to the resonant circuit, the control circuit configured to:
detect whether an event of a voltage across the first capacitor or a current of the transmitter coil occurs; and
when detecting that the event occurs, control to turn on the first switch in response to a signaling of turning on the first switch.

2. The apparatus of claim 1, wherein the event comprises: the voltage across the first capacitor reaches a peak voltage of the first capacitor.

3. The apparatus of claim 1, wherein the event comprises: the voltage across the first capacitor is greater than a voltage threshold.

4. The apparatus of claim 1, wherein the event comprises: the current of the transmitter coil is zero-crossing.

5. The apparatus of claim 1, wherein the event comprises: the current of the transmitter coil is less than a current threshold.

6. The apparatus of claim 1, wherein:
the first switch is a back-to-back switch; and
the event comprises: the voltage across the first capacitor is zero-crossing.

7. The apparatus of claim 1, wherein:
the first switch is a back-to-back switch; and
the event comprises: the current of the transmitter coil reaches a peak current of the transmitter coil.

8. The apparatus of claim 1, wherein the event comprises: a difference between the voltage across the first capacitor and a voltage across the second capacitor with the first switch turned off is less than a voltage threshold.

9. The apparatus of claim 1, further comprising a transmitter switch circuit connected to the resonant circuit, wherein the transmitter switch circuit comprises:
a first power switch and a second power switch connected in series between an power source and ground, wherein a common node of the first power switch and the second power switch is connected to a first terminal of the transmitter coil; and
a third power switch and a fourth power switch connected in series between the power source and the ground, wherein a common node of the third power switch and the fourth power switch is connected to a second terminal of the transmitter coil through the first capacitor.

10. The apparatus of claim 1, wherein the control circuit is further configured to:
when the event does not occur, and in response to the signaling of turning on the first switch, control to turn on the first switch at a drive voltage that is variable so as to adjust an on-resistance of the first switch to allow a current flowing through the first switch to increase at a predetermined rate.

11. The apparatus of claim 10, wherein the control circuit is further configured to:
when a difference between the voltage across the first capacitor and a second voltage is less than a voltage threshold, control to turn on the first switch completely, the second voltage being a voltage across the second capacitor with the first switch turned on at the drive voltage.

12. The apparatus of claim 1, wherein the control circuit is further configured to:
when the event does not occur, and in response to the signaling of turning on the first switch, control to turn on the first switch at a predetermined drive voltage, the predetermined drive voltage generating an on-resistance of the first switch that limits a current flowing through the first switch below a current threshold.

13. A method applied to a wireless power transmitter, wherein the wireless power transmitter comprises: a first capacitor and a transmitter coil connected in series; and a second capacitor connected in series with a first switch, wherein the second capacitor and the first switch are connected in parallel with the first capacitor; and
wherein the method comprises:
detecting whether an event of a voltage across the first capacitor or a current of the transmitter coil occurs; and
when the event occurs, controlling to turn on the first switch in response to a signaling of turning on the first switch.

14. The method of claim 13, wherein detecting whether the event occurs comprises:
detecting that the event occurs when the voltage across the first capacitor reaches a peak voltage of the first capacitor; or
detecting that the event occurs when the current of the transmitter coil is zero-crossing.

15. The method of claim 13, wherein:
the first switch is a back-to-back switch; and
detecting whether the event occurs comprises:
detecting that the event occurs when the voltage across the first capacitor is zero-crossing; or
detecting that the event occurs when the current of the transmitter coil reaches a peak current of the transmitter coil.

16. The method of claim 11, wherein detecting whether the event occurs comprises:
detecting that the event occurs when a difference between the voltage across the first capacitor and a voltage across the second capacitor with the first switch turned off is less than a voltage threshold.

17. The method of claim 11, further comprising:
when detecting that the event does not occur, and in response to the signaling of turning on the first switch, controlling to turn on the first switch at a drive voltage that is variable so as to adjust an on-resistance of the first switch to allow a current flowing through the first switch to increase at a predetermined rate; and
when a difference between the voltage across the first capacitor and a second voltage is less than a voltage threshold, controlling to turn on the first switch completely, the second voltage being a voltage across the second capacitor with the first switch turned on at the drive voltage.

18. A controller comprising:
a circuit configured to:
detect a voltage across a first capacitor of a capacitor bank or a current of a transmitter coil, wherein the capacitor bank is connected with the transmitter coil in series, and the capacitor bank further comprises a second capacitor connected in series with a first switch, with the second capacitor and the first switch being connected in parallel with the first capacitor;
determine whether the voltage across the first capacitor or the current of the transmitter coil satisfies a predetermined condition; and
when the voltage across the first capacitor or the current of the transmitter coil satisfies the predetermined condition, control to turn on the first switch in response to receipt of a signaling of turning on the first switch.

19. The controller of claim 18, wherein:
the voltage across the first capacitor satisfies the predetermined condition when the voltage across the first capacitor reaches a peak voltage of the first capacitor; and
the current of the transmitter coil satisfies the predetermined condition when the current of the transmitter coil is zero-crossing.

20. The controller of claim 18, wherein:
the first switch is a back-to-back switch;
the voltage across the first capacitor satisfies the predetermined condition when the voltage across the first capacitor is zero-crossing; and
the current of the transmitter coil satisfies the predetermined condition when the current of the transmitter coil reaches a peak current of the transmitter coil.
